(19) United States
(12) Patent Application Publication
(10) Pub. No.: US 2026/0215210 A1
(43) Pub. Date: Jul. 23, 2026

(54) SYSTEM FOR SEPARATING LED ELEMENT, AND METHOD FOR SEPARATING LED ELEMENT

(71) Applicant: ADVANCED VIEW TECHNOLOGY INC., Ansan-si, Gyeonggi-do (KR)

(72) Inventors: Gyeong-Won LEE, Ansan-si, Gyeonggi-do (KR); Ji-Eun PARK, Ansan-si, Gyeonggi-do (KR)

(73) Assignee: ADVANCED VIEW TECHNOLOGY INC., Ansan-si, Gyeonggi-do (KR)

(21) Appl. No.: 19/142,410

(22) PCT Filed: Oct. 20, 2023
(86) PCT No.: PCT/KR2023/016402

§ 371 Date: Jun. 23, 2025

(30) Foreign Application Priority Data
Dec. 23, 2022 (KR) 10-2022-0182435

(51) Int. Cl. H10P 72/00; H10H 20/01

(52) U.S. Cl. CPC H10P 72/0448; H10H 20/019

(57) ABSTRACT

A system for separating an LED element using a hydrophobically modified LED element, includes: a first accommodating part for accommodating a substrate on which a plurality of LED elements are formed and an organic solvent; a second accommodating part disposed outside the first accommodating part and accommodating the first accommodating part and a fluid; a plurality of ultrasonic wave generating parts disposed under the second accommodating part and applying ultrasonic waves to the substrate; and a passage part which is connected to the second accommodating part and through which the fluid circulates, wherein the plurality of LED elements include a modifying compound on the surface thereof. The modifying compound includes a hydrophilic functional group located on the surface of the LED element and a hydrophobic functional group located on the opposite side of the hydrophilic functional group.

### CROSS-REFERENCE TO PRIOR APPLICATIONS

This application is a National Stage Patent Application of PCT International Application No. PCT/KR2023/016402 (filed on Oct. 20, 2023), which claims priority to Korean Patent Application No. 10-2022-0182435 (filed on Dec. 23, 2022), which are all hereby incorporated by reference in their entirety.

### BACKGROUND

The present invention relates to a system for separating an LED element and a method for separating an LED element, which can efficiently separate an LED element from a substrate using high-frequency ultrasonic waves and LED elements surface-treated with a low-molecular-weight modifying compound.

A light-emitting element may be manufactured through an epitaxial growth method that grows a semiconductor crystal on a wafer substrate.

A plurality of semiconductor layers may be grown on a wafer substrate and then separated from the wafer substrate to manufacture a light-emitting element. In this case, in the process of separating the light-emitting element, a method of separating the semiconductor layer grown on the substrate by applying mechanical force may be used.

However, since the process using mechanical force is performed manually by a worker, there is a problem that the process time is long and the cut surface of the separated light-emitting element is not uniform and is damaged.

Meanwhile, a method of separating a light-emitting element from a substrate using equipment called a laser lift-off has been used, but it has a disadvantage in that it is difficult to capture all of the separated light-emitting elements, resulting in a low separation yield.

Therefore, there is a need for a technology capable of efficiently separating a light-emitting element from a substrate.

### SUMMARY

An object of the present invention is to provide an LED element separation system capable of improving the aggregation of LED elements during the separation process.

Another object of the present invention is to provide an LED element separation system capable of improving the yield of an LED element separated from a substrate.

Still another object of the present invention is to provide a method for separating an LED element that can separate a hydrophobically modified LED element in an organic solvent by using high-frequency ultrasonic waves, thereby preventing external loss and improving the uniformity of the length of the LED element.

The objects of the present invention are not limited to the above-mentioned objects, and other objects and advantages of the present invention that are not mentioned can be understood by the following description, and will be more clearly understood by the examples of the present invention. In addition, it will be easily understood that the objects and advantages of the present invention can be realized by means indicated in the claims and combinations thereof.

A system for separating an LED element using a hydrophobically modified LED element according to the first embodiment of the present invention comprises: a first accommodating part for accommodating a substrate on which a plurality of LED elements are formed and an organic solvent; a second accommodating part disposed outside the first accommodating part and accommodating the first accommodating part and a fluid; a plurality of ultrasonic wave generating parts disposed under the second accommodating part and applying ultrasonic waves to the substrate; and a passage part which is connected to the second accommodating part and through which the fluid circulates, wherein the plurality of LED elements include a modifying compound in the surface layer thereof, wherein the modifying compound includes a hydrophilic functional group located on the surface of the LED element and a hydrophobic functional group located on the opposite side of the hydrophilic functional group.

The modifying compound may have a weight average molecular weight of 500 g/mol or less.

The hydrophilic functional group of the modifying compound may include phosphonic acid, and the hydrophobic functional group may include a C1 to C18 alkyl group.

The organic solvent accommodated in the first accommodating part may be maintained at a temperature of 20 to 30° C.

The plurality of ultrasonic wave generating parts may apply ultrasonic waves to one surface of the substrate in a direction perpendicular thereto and may be driven simultaneously.

A cooling part located in the passage part may further be included.

According to the second embodiment of the present invention, a method for separating a plurality of LED elements from a substrate on which the plurality of LED elements are formed, the method including the steps of: (a) disposing an ultrasonic wave generating part under an accommodating part and introducing the substrate on which the plurality of LED elements are formed and an organic solvent into the accommodating part; and (b) applying ultrasonic waves to the substrate to generate bubbles in the organic solvent, and allowing the generated bubbles to penetrate between the plurality of LED elements to separate the plurality of LED elements from the substrate, wherein in the step (a), the plurality of LED elements formed on the substrate are disposed so as to face toward an upper portion of the accommodating part.

According to the third embodiment of the present invention, a method for separating a plurality of LED elements from a substrate on which the plurality of LED elements are formed, the method including the steps of: (a) disposing an ultrasonic wave generating part under an accommodating part and introducing the substrate on which the plurality of LED elements are formed and an organic solvent into the accommodating part; and (b) applying ultrasonic waves to the substrate to generate bubbles in the organic solvent, and allowing the generated bubbles to penetrate between the plurality of LED elements to separate the plurality of LED elements from the substrate, wherein in the step (a), the plurality of LED elements formed on the substrate are disposed so as to face toward a lower portion of the accommodating part, and wherein the plurality of LED elements include a modifying compound in the surface layer thereof, wherein the modifying compound includes a hydrophilic functional group located on the surface of the LED element and a hydrophobic functional group located on the opposite side of the hydrophilic functional group.

According to the third embodiment, the step (a) may include: (a1) a step of providing an accommodating part under which an ultrasonic wave generating part is disposed and introducing an organic solvent into the accommodating part; (a2) a step of attaching a holder to the opposite side of a substrate on which the plurality of LED elements are formed, and then vertically moving the holder to introduce the substrate into the accommodating part; (a3) a step of measuring a height of the organic solvent and matching a surface of the substrate with a surface of the organic solvent; and (a4) a step of matching an interface between the substrate and the LED element with a node position of a standing wave using Equations 1 and 2 below:

Wavelength of ultrasonic wave (λ)=Speed of ultrasonic wave in organic solvent (v)/Vibration frequency of ultrasonic wave generating part (f) [Equation 1]

Node position of standing wave (cm)=Integer (n) of 1 to 10×Wavelength of ultrasonic wave (λ)/2 [Equation 2]

In addition, when a vertical movement distance of the substrate to which the holder is attached from the surface of the organic solvent is D, and a height of the organic solvent is L,

D=L−Node position of standing wave (cm) may be satisfied. [Equation 3]

According to the second embodiment or the third embodiment, a size of the bubble may be smaller than a gap between one LED element and another LED element formed on the substrate.

According to the second embodiment or the third embodiment, in the step (b), the vibration frequency of the ultrasonic wave generating part may be 120 to 200 kHz.

In this case, the modifying compound may have a weight average molecular weight of 500 g/mol or less. In addition, the hydrophilic functional group of the modifying compound may include phosphonic acid, and the hydrophobic functional group may include a C1 to C18 alkyl group.

The LED element separation system according to the present invention can increase the separation efficiency of LED elements by separately having an accommodating part for accommodating the LED elements.

In addition, by using a modifying compound to bind a hydrophilic functional group to the surface of the LED element and a hydrophobic functional group to the opposite side, the aggregation phenomenon of the LED elements in the organic solvent during the separation process can be improved. In addition, by using a passage part through which the fluid circulates to maintain the organic solvent inside the accommodating part at a constant temperature, the aggregation phenomenon of the LED elements can be minimized.

The LED element separation method according to the present invention can separate LED elements in an organic solvent by using high-frequency ultrasonic waves, thereby preventing external loss and improving the uniformity of the length of the LED element.

In addition to the above-described effects, the specific effects of the present invention will be described together with the specific matters for implementing the invention below.

### BRIEF DESCRIPTION OF THE DRAWINGS

FIG. 1 is a side view of an LED element separation system according to the first embodiment of the present invention.

FIG. 2 is a plan view of an LED element separation system according to the first embodiment of the present invention.

FIG. 3 is an image of aggregated LED elements (a) and an image of LED elements with secured dispersibility (b).

FIG. 4 is a schematic diagram showing an LED element separation method according to the second embodiment of the present invention.

FIG. 5 is a schematic diagram showing an LED element separation method according to the third embodiment of the present invention.

FIG. 6 is a graph showing the separation yield of LED elements according to frequency in the second and third embodiments of the present invention.

### DESCRIPTION OF REFERENCE NUMERALS

10: First accommodating part
20: Second accommodating part
30, 33, 35: Ultrasonic generating part
40: Passage part
50: Cooling part
100, 200: Accommodating part
220, 320: Substrate
230, 330: Microbubble
400: Holder
500: z-axis adjustment stage

### DETAILED DESCRIPTION

The above-described objects, features, and advantages will be described in detail below with reference to the attached drawings, and thus those skilled in the art may easily implement the technical idea of the present invention. In describing the present invention, if it is determined that detailed descriptions of the known technology related to the present invention may unnecessarily obscure the gist of the present invention, the detailed description thereof will be omitted. Hereinafter, a preferred embodiment according to the present invention will be described in detail with reference to the accompanying drawings. In the drawings, the same reference numerals are used to indicate the same or similar components.

When any component is disposed “on (or under)” a component or “above (or below)” a component below, this may mean not only that any component is disposed in contact with the upper surface (or lower surface) of said component, but also that other components may be interposed between said component and any component disposed on (or under) said component.

In addition, when it is described that a component is “connected”, “coupled” or “joined” to another component, it should be understood that the components may be directly connected or joined to each other, but that other components may be “interposed” between the respective components, or that the respective components may be “connected”, “coupled” or “joined” through another component.

Hereinafter, a system for separating an LED element and a method for separating an LED element according to some embodiments of the present invention will be described.

The first embodiment of the present invention relates to an LED element separation system capable of efficiently separating a plurality of LED elements from a substrate without agglomeration of LED elements in an organic solvent by applying ultrasonic waves to hydrophobically modified LED elements.

The LED element separation system according to the first embodiment of the present invention is characterized by comprising: a first accommodating part 10 for accommodating a substrate on which a plurality of LED elements are formed and an organic solvent; a second accommodating part 20 disposed outside the first accommodating part and accommodating the first accommodating part and a fluid; a plurality of ultrasonic wave generating parts 30 disposed under the second accommodating part and applying ultrasonic waves to the substrate; and a passage part 40 which is connected to the second accommodating part and through which the fluid circulates. In this case, it is preferable that the plurality of LED elements include a modifying compound in the surface layer thereof, wherein the modifying compound includes a hydrophilic functional group located on the surface of the LED element and a hydrophobic functional group located on the opposite side of the hydrophilic functional group. The fact that the plurality of LED elements include a modifying compound may mean that the modifying compound is dispersed in the surface layer of the element, or that the modifying compound is coupled to or dispersed in an insulating layer.

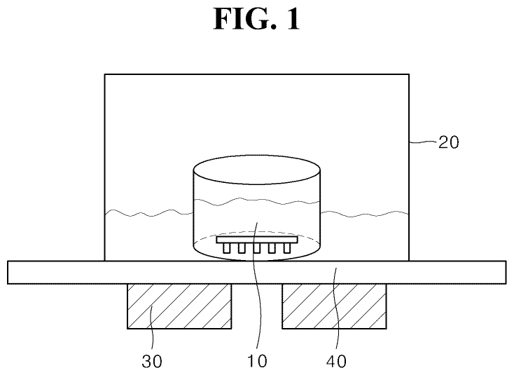

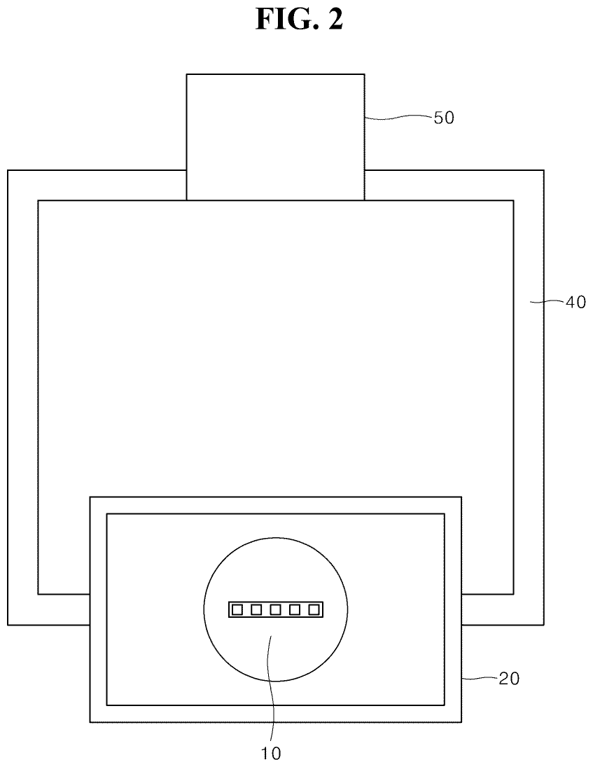

As shown in FIGS. 1 and 2, the LED element separation system can increase the separation efficiency of the LED elements by using at least two ultrasonic wave generating parts located under the second accommodating part, and can maintain the temperature of the organic solvent in the second accommodating part at room temperature by using fluid circulation. This has the effect of preventing the aggregation of the LED elements due to heat generation when ultrasonic waves are applied.

In particular, when a plurality of LED elements are modified using a modifying compound having a hydrophilic functional group and a hydrophobic functional group before separating the LED elements from the substrate, the hydrophilic functional group is bonded to the surface of the insulating layer of the LED element, and the hydrophobic functional group is positioned on the opposite side of the hydrophilic functional group, so that the insulating layer in the outermost layer of the LED element can be surface-treated with the hydrophobic functional group. Accordingly, the surface of the LED element is hydrophobically treated, so that the aggregation of the LED elements in the organic solvent can be further prevented.

The first accommodating part 10 is a space in which the substrate on which a plurality of LED elements are formed and an organic solvent are accommodated, and the LED elements are separated. Since the organic solvent contained in the first accommodating part is not circulated to the outside, the LED elements can be completely separated and obtained within the first accommodating part. In other words, by disposing a separate first accommodating part inside the first accommodating part, there is an effect of further improving the separation efficiency of the LED elements.

The first accommodating part may be formed of a solid material so that external deformation does not occur due to ultrasonic waves. For example, the first accommodating part may be formed of glass or metal, but is not limited thereto.

The length of the bottom surface of the first accommodating part may be about 1 to 10% greater than the length of the substrate. When the length of the bottom surface of the first accommodating part is about 1 to 10% greater than the length of the substrate, the movement of the substrate can be minimized. Since the substrate is not greatly shaken while being separated by ultrasonic waves, the substrate can be stably fixed within the first accommodating part, and the LED elements can be stably separated from the substrate. Conversely, when the length of the bottom surface of the first accommodating part is more than 10% greater than the length of the substrate, there is a lot of empty space inside the first accommodating part, so that the substrate is greatly shaken when ultrasonic waves are applied. Accordingly, the aggregation of separated LED elements may be caused by friction between the substrate and the bottom surface of the first accommodating part.

The organic solvent may include isopropyl alcohol (IPA), acetone, ethanol, methanol, etc.

The substrate on which a plurality of LED elements are formed has a structure in which the LED elements are grown through an epitaxial growth method, and the plurality of LED elements are spaced apart from each other.

The substrate may include a known sapphire substrate, a transparent substrate such as glass, but is not limited thereto. The LED element may have a length of 3 to 10 μm and a diameter of 0.1 to 10 μm, preferably a length of 4 to 6 μm and a diameter of 0.5 to 2 μm, but is not limited thereto. In addition, the LED element may be cylindrical or rod-shaped.

The LED element may include an insulating layer in an outermost layer so as to surround a plurality of semiconductor layers and electrode layers. The insulating layer may include silicon oxide (SiOₓ, 0<x<2), silicon nitride (SiNₓ, 0<x<2), silicon oxynitride (SiOₓN_{y}, 0<x, y<2), aluminum nitride (AlN), etc, but is not limited thereto.

In order to efficiently separate and disperse the plurality of LED elements formed on the substrate in an organic solvent, a process of improving the hydrophobicity of the LED elements through pretreatment is necessary.

In order to minimize the aggregation of the LED elements in the organic solvent, it is important to impart hydrophobicity to the insulating layer formed on the LED elements.

From this perspective, the modification reaction of LED elements may be performed by dipping the substrate on which a plurality of LED elements are formed into a modifying compound.

It is preferable that the plurality of LED elements include a modifying compound constituting a surface treatment layer, wherein the modifying compound preferably includes a hydrophilic functional group located on the surface of the LED element and a hydrophobic functional group located on the opposite side of the hydrophilic functional group. When a region has a higher solubility in water than other regions, the region is said to have hydrophilicity, and when a region has a lower solubility in water than other regions, the region is said to have hydrophobicity.

The surfaces of the plurality of LED elements formed on the substrate are pretreated to be hydrophobic by a modifying compound, so that the LED elements can be efficiently separated from the substrate in an organic solvent. By applying ultrasonic waves, the LED elements can be maintained in a dispersed state in the organic solvent for a certain period of time.

The modifying compound may include a hydrophilic functional group such as phosphonic acid and a hydrophobic functional group such as a C1 to C18 alkyl group. Here, the hydrophobic functional group may include, for example, a methyl group.

When the modifying compound includes phosphonic acid and a C1 to C18 alkyl group, the phosphonic acid binds to the insulating layer of the LED element, so that the LED element can be sufficiently modified to be hydrophobic. Accordingly, the aggregation of LED element particles can be controlled during the separation process of the LED elements, and the separation yield of the LED elements can be further increased.

The modifying compound may have a weight average molecular weight of 500 g/mol or less, preferably 100 to 400 g/mol, and more preferably 200 to 350 g/mol.

The modifying compound has the effect of inducing independent arrangement of LED elements to secure dispersibility by satisfying a weight average molecular weight of 500 g/mol or less. The modifying compound may include a compound as shown in Table 1 below.

TABLE 1

| Name | Chemical formula | MW |
|---|---|---|
| Methylphosphonic acid (MPA) | CH₃PO(OH)₂ | 96.02 |
| Ethylphosphonic acid | C₂H₅PO(OH)₂ | 110.05 |
| Hexylphosphonic acid (HPA) | C₆H15O₃P | 166.16 |
| Octylphosphonic acid (OPA) | C₈H₁₉O₃P | 194.21 |
| Decylphosphonic acid | C₁₀H₂₃O₃P | 222.26 |
| N-Dodecylphosphonic acid (DDPA) | C₁₂H₂₇O₃P | 250.31 |
| Tetradecylphosphonic acid | CH₃(CH₂)₁₃PO(OH)₂ | 278.37 |
| Hexadecylphosphonic acid (HDPA) | C₁₆H₃₅O₃P | 306.42 |
| Octadecylphosphonic acid (ODPA) | C₁₈H₃₉O₃P | 334.47 |

The organic solvent contained in the first accommodating part may be maintained at 20 to 30° C., preferably at 23 to 28° C., and more preferably at 24 to 26° C.

The organic solvent is maintained at 20 to 30° C. by a cooling part 50 located in a passage part, and the temperature of the organic solvent in the first accommodating part is lowered as a fluid moving along the passage part is cooled by the cooling part.

Conventionally, the LED elements were separated from the substrate in a volatile solvent such as an alcohol-based solvent, but the temperature inside the accommodating part increased as heat was generated when ultrasonic waves were applied, resulting in aggregation between the LED elements due to volatilization of the solvent.

In order to solve these conventional problems, the separation system of the present invention installs a passage part and a cooling part, and uses a modifying compound having a composition of a low molecular weight phosphonic acid series, thereby significantly improving the aggregation phenomenon of LED elements.

Therefore, it is preferable to install the cooling part at an arbitrary location in the passage part to lower the temperature of the organic solvent.

The second accommodating part 20 serves to store and protect the first accommodating part, and a fluid is accommodated in the second accommodating part so that the heat generated by the ultrasonic waves can be circulated by the fluid. The second accommodating part may be formed of metal, but is not limited thereto.

In order to apply ultrasonic waves uniformly to the entire surface of the substrate, a plurality of ultrasonic wave generating parts may apply ultrasonic waves in a direction perpendicular to one surface of the substrate, and the plurality of ultrasonic wave generating parts may be driven simultaneously.

The ultrasonic wave generating part 30 may have a probe-type shape. The probe-type ultrasonic wave generating part does not apply ultrasonic waves while moving in a stamp manner, but stably applies ultrasonic waves at a fixed location, and applies ultrasonic waves only to a corresponding position where the ultrasonic wave generating part is placed, so that only the LED elements at the corresponding position can be stably and efficiently separated.

For example, when two ultrasonic wave generating parts are disposed at positions A and B, ultrasonic waves may be applied in the upper direction of position A and the upper direction of position B.

The ultrasonic wave generating part may be connected to an external device to be applied with voltage for generating ultrasonic waves, and may be an ultrasonic transducer that converts electrical energy into mechanical vibration.

In particular, in the present invention, since at least two ultrasonic wave generating parts are disposed in direct contact with the lower portion of the second accommodating part, a distance between the substrate and the ultrasonic wave generating parts can be narrowed, thereby increasing the ultrasonic generation effect and enabling smooth separation of the LED elements. In addition, since two or more ultrasonic wave generating parts are driven simultaneously, ultrasonic waves of a uniform size can be applied in a certain direction, thereby further increasing the separation efficiency of the LED elements.

The passage part 40 is a passage through which a fluid circulates in one direction, and may be connected to the second accommodating part at one side and the other side thereof. Alternatively, the passage part may be located between the plurality of ultrasonic wave generating parts while being located below the second accommodating part.

The fluid may be distilled water, or an antifreeze in which water and ethylene glycol are mixed. The fluid is discharged from the cooling part, moves along the pipe-shaped passage part, passes through the lower portion of the second accommodating part, and flows into the cooling part. Since the fluid discharged from the cooling part has a relatively low temperature, it provides an advantage in further lowering the temperature of the organic solvent in the first accommodating part.

The cooling part 50 may be located adjacent to or opposite the second accommodating part, and preferably opposite the second accommodating part so as to uniformly control the amount and speed of the fluid cooled by the cooling part and the fluid flowing into the cooling part.

Any structure capable of lowering the temperature of the fluid may be used without limitation.

As described above, the LED element separation system according to the first embodiment of the present invention uses the LED elements surface-treated with a low-molecular-weight modifying compound, the second accommodating part that accommodates the first accommodating part and the fluid as a dedicated beaker, the plurality of ultrasonic wave generating parts, and the passage part that circulates the fluid, thereby having the effect of efficiently separating a plurality of LED elements from a substrate without aggregation of the LED elements in an organic solvent.

A method for separating an LED element using the LED element separation system according to the first embodiment is as follows.

A first accommodating part and a second accommodating part are provided, and then the first accommodating part is placed inside the second accommodating part. The first accommodating part can accommodate a substrate on which a plurality of LED elements are formed and an organic solvent, and the second accommodating part can accommodate a fluid.

Using a plurality of ultrasonic wave generating parts, ultrasonic waves are applied to the substrate in a direction perpendicular to one surface of the substrate, and the plurality of ultrasonic wave generating parts are driven simultaneously to perform separation and dispersion operations of the LED elements.

At this time, by using a passage part connected to the second accommodating part and a cooling part located in the passage part, the fluid is circulated inside the passage part, so that the organic solvent accommodated in the first accommodating part can be maintained at a temperature of 20 to 30° C.

When all the LED elements are separated from the substrate in the organic solvent, the power of the cooling part and the ultrasonic wave generating parts is turned off, and the substrate and LED elements included in the organic solvent are filtered, so that the LED elements can be efficiently obtained in a short period of time. In addition, since separation occurs within the solution using ultrasonic wave, there is an advantage in that there is no external loss and the uniformity of the length of the LED element is high.

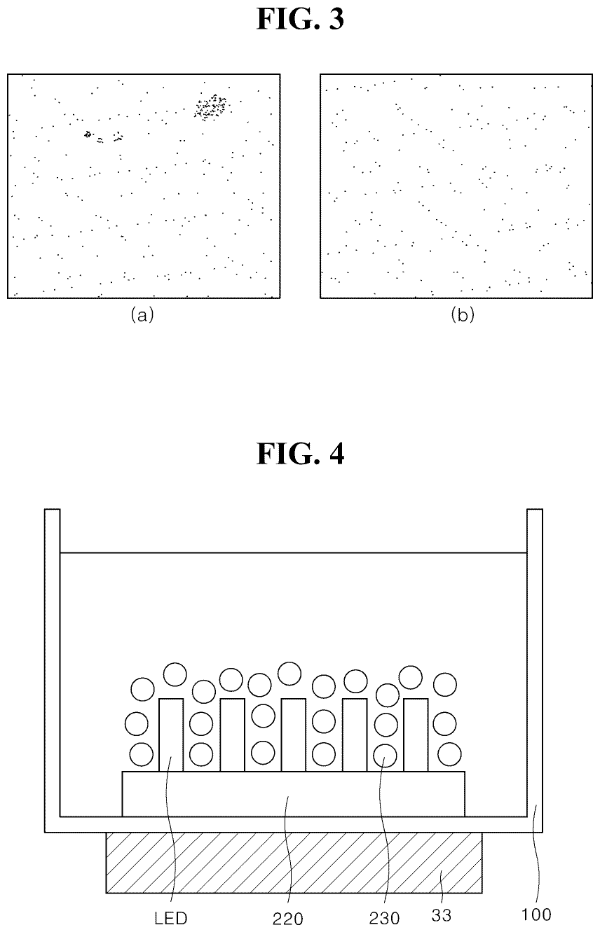

FIG. 3 is an image of aggregated LED elements (a) and an image of LED elements with secured dispersibility (b).

FIG. 3(a) is an image in which a first accommodating part accommodating a plurality of LED elements that have not been hydrophobically treated is provided, multiple probe-type ultrasonic waves are applied in a direction perpendicular to one surface of the substrate, and fluid circulation is excluded and thus the temperature of the organic solvent is 30° C.

FIG. 3(b) is an image using the separation system according to the first embodiment, in which a first accommodating part accommodating a plurality of LED elements modified with a modifying compound (ODPA: 500 g/mol, IPA mixture) is provided, multiple probe-type ultrasonic waves are applied in a direction perpendicular to one surface of the substrate, and the organic solvent is maintained at a temperature of 20 to 23° C. through fluid circulation.

The measurement method of FIG. 3 was performed using an objective lens of 50× and a tube lens of 0.5× based on an optical microscope. Separation yields at 10 to 20 positions of LED elements were measured in consideration of sample position deviations, and then the aggregated image (a) and the dispersed image (b) were compared based on the average value.

In FIG. 3(a), the LED element surface was not hydrophobically treated, so aggregation occurred immediately after the LED elements were separated from the LED substrate, and aggregation occurred quickly due to an increase in the temperature of the organic solvent.

On the other hand, in FIG. 3(b), it was confirmed that by using LED elements hydrophobically pretreated with ODPA and maintaining the organic solvent at 25° C. or lower through fluid circulation, the dispersibility between the LED elements in the organic solvent was improved, enabling long-term storage and use.

The second embodiment of the present invention relates to an LED element separation method capable of efficiently separating a plurality of LED elements by disposing a plurality of LED elements formed on a substrate so as to face upward and utilizing microbubbles generated when high-frequency ultrasonic waves are applied to the substrate.

Furthermore, the third embodiment of the present invention relates to an LED element separation method capable of efficiently separating a plurality of LED elements from a substrate by disposing a plurality of LED elements formed on a substrate so as to face downward and utilizing high-frequency ultrasonic waves and wave energy (shock wave).

According to the second and third embodiments, a plurality of LED elements can be surface-treated with a modifying compound including a hydrophilic functional group located on the surface of the LED element and a hydrophobic functional group located on the opposite side of the hydrophilic functional group, and since separation of the LED elements occurs through microbubbles in an organic solvent, there is an effect that there is no external loss and the uniformity of the length of the LED elements is improved.

According to the second embodiment of the present invention, a method for separating a plurality of LED elements from a substrate on which the plurality of LED elements are formed is characterized by including the steps of: disposing an ultrasonic wave generating part under an accommodating part and introducing the substrate on which the plurality of LED elements are formed and an organic solvent into the accommodating part; and applying ultrasonic waves to the substrate to generate bubbles in the organic solvent, and allowing the generated bubbles to penetrate between the plurality of LED elements to separate the plurality of LED elements from the substrate.

In this case, in the introducing step, it is preferable that the plurality of LED elements formed on the substrate are disposed so as to face toward an upper portion of the accommodating part.

FIG. 4 is a schematic diagram showing an LED element separation method according to the second embodiment of the present invention.

As illustrated in FIG. 4, a plurality of LED elements can be separated from a substrate 220 by using an accommodating part 100 under which an ultrasonic wave generating part 33 is disposed.

The accommodating part 100 is a space in which the substrate on which a plurality of LED elements are formed and an organic solvent are accommodated, and the LED elements are separated. Since the organic solvent contained in the accommodating part is not circulated to the outside, the LED elements can be completely separated and obtained within the accommodating part. The accommodating part may be formed of a solid material so that external deformation does not occur due to ultrasonic waves. For example, the accommodating part may be formed of glass or metal, but is not limited thereto.

In order to apply ultrasonic waves uniformly to the entire surface of the substrate, the ultrasonic wave generating parts 33 may apply ultrasonic waves in a direction perpendicular to one surface of the substrate, and the plurality of ultrasonic wave generating parts may be driven simultaneously. The ultrasonic wave generating part includes a plurality of ones having a probe-type shape, and does not apply ultrasonic waves while moving in a stamp manner, but stably applies ultrasonic waves at a fixed location, and applies ultrasonic waves only to a corresponding position where the ultrasonic wave generating part is placed, so that only the LED elements at the corresponding position can be stably and efficiently separated. In particular, the plurality of ultrasonic wave generating parts may be disposed in direct contact with the lower surface of the accommodating part. The ultrasonic wave generating part may be connected to an external device to be applied with voltage for generating ultrasonic waves, and may be an ultrasonic transducer that converts electrical energy into mechanical vibration.

The substrate on which a plurality of LED elements are formed and an organic solvent may be introduced simultaneously into the accommodating part, or the substrate and the organic solvent may be introduced sequentially, or the organic solvent and the substrate may be introduced sequentially. However, in order to minimize damage to the LED elements, it is preferable to introduce the substrate after introducing the organic solvent. In addition, when introducing the organic solvent, the amount of the organic solvent may be adjusted so that the substrate is sufficiently immersed in the organic solvent.

In this case, the direction of the substrate on which a plurality of LED elements are formed may be set. The substrate may be disposed so that it is adjacent to the ultrasonic wave generating part and parallel to the lower surface of the accommodating part and the LED elements are perpendicular to the lower surface of the accommodating part, and then the dispersion step may be performed. When the substrate is disposed in this way, the microbubbles generated while applying the ultrasonic waves can penetrate between the LED elements in a uniform amount, so that the LED elements can be stably separated and stored in the organic solvent.

Since the substrate on which a plurality of LED elements are formed and the organic solvent are the same as those described above in the first embodiment, their description will be omitted.

When ultrasonic waves are applied to the substrate, pressure is generated in the organic solvent, and micro bubbles such as cavities are created. Since cavitation energy is transferred during the process of creating micro bubbles, force is applied between the substrate and the LED elements, and thus the LED elements can be separated.

That is, the bubbles generated in the organic solvent by ultrasonic waves penetrate between a plurality of LED elements, so that the plurality of LED elements can be separated from the substrate.

The generally used ultrasonic frequency is low frequency, and the bubble size is very large. When the bubble size is large, the bubble cannot penetrate between the plurality of LED elements, and therefore, there is a problem that the bubble transmission efficiency is extremely low.

In order to solve this problem, as shown in FIG. 4, the present invention significantly increases the separation efficiency of the LED elements by controlling the bubble size using a high frequency of ultrasonic waves.

In order to apply a high frequency of ultrasonic waves, the vibration frequency of the ultrasonic wave generating part is preferably 120 to 200 kHz, more preferably 120 to 180 kHz, and even more preferably 125 to 160 KHz.

When the vibration frequency satisfies 120 to 200 kHz, it is advantageous to generate microbubbles in the organic solvent, and there is an effect of efficiently separating a plurality of LED elements formed on the substrate within a short period of time. In particular, in the range of the vibration frequency of 120 to 200 kHz, the separation yield of the LED elements can be 60% or more, and preferably 70% or more. The separation yield may be calculated as [1−(area occupied by the LED elements on the substrate after separation/area occupied by the LED elements on the substrate before separation)]×100%.

In order to improve the separation efficiency of the LED elements, the size of the bubbles in the organic solvent may be smaller than a gap between one LED element and another LED element formed on the substrate. In addition, since the bubbles generated by the ultrasonic wave tend to decrease as the frequency increases, it is important to control the bubble size in consideration of the frequency and the gap between the LED elements. For example, the LED element may have a length of 3 to 10 μm and a diameter of 0.1 to 10 μm, and the bubble size may be 1 to 10 μm, and preferably 2 to 5 μm.

As described above, the LED element separation method according to the second embodiment of the present invention uses high-frequency ultrasonic waves in a state where the direction of the LED elements formed on the substrate faces upward, thereby having the effect of separating the plurality of LED elements so that the length and cut surface of the LED elements are uniform through the microbubbles.

According to the third embodiment of the present invention, a method for separating a plurality of LED elements from a substrate on which the plurality of LED elements are formed is characterized by including the steps of: disposing an ultrasonic wave generating part under an accommodating part and introducing the substrate on which the plurality of LED elements are formed and an organic solvent into the accommodating part; and applying ultrasonic waves to the substrate to generate bubbles in the organic solvent, and allowing the generated bubbles to penetrate between the plurality of LED elements to separate the plurality of LED elements from the substrate.

In this case, in the step of introducing the substrate on which a plurality of LED elements are formed and the organic solvent, it is preferable that the plurality of LED elements formed on the substrate are disposed so as to face toward a lower portion of the accommodating part. The reason for disposing the substrate in this manner is to maximize the separation efficiency of the LED elements by applying wave energy together with high-frequency ultrasonic waves and positioning the interface between the substrate and the LED elements at a position where the amplitude of the standing wave is maximum.

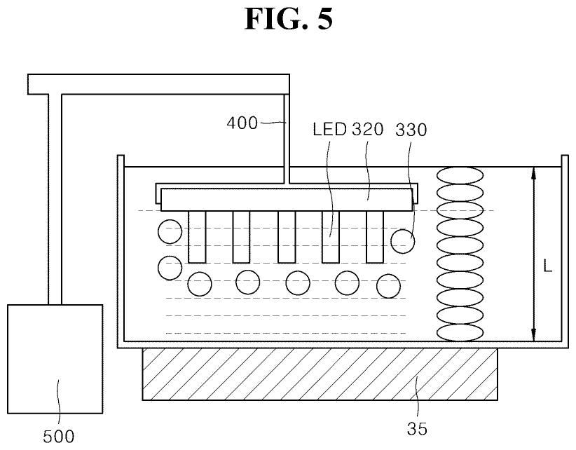

FIG. 5 is a schematic diagram showing an LED element separation method according to the third embodiment of the present invention.

As shown in FIG. 5, by vertically moving the substrate 320 in the organic solvent and matching the interface between the substrate and the LED element with the node position of the standing wave, the separation efficiency of the LED elements is maximized. The size of the bubble illustrated in FIG. 5 is only one embodiment and is not limited thereto.

The accommodating part 200 under which the ultrasonic wave generating part 35 is disposed is the same as the accommodating part 100 in which the ultrasonic wave generating part 33 is disposed according to the second embodiment, so a description thereof will be omitted.

The LED element separation method can vertically move the substrate 320 in the organic solvent by using equipment in which a holder 400 is provided (connected) to a z-axis adjustment stage 500.

Specifically, the step of introducing the substrate and the organic solvent may include the steps of: providing an accommodating part under which an ultrasonic wave generating part is disposed and introducing an organic solvent into the accommodating part; attaching a holder to the opposite side of a substrate on which the plurality of LED elements are formed, and then vertically moving the holder to introduce the substrate into the accommodating part; measuring a height of the organic solvent and matching a surface of the substrate with a surface of the organic solvent; and matching an interface between the substrate and the LED element with a node position of a standing wave using Equations 1 and 2 below:

Wavelength of ultrasonic wave (λ)=Speed of ultrasonic wave in organic solvent (v)/Vibration frequency of ultrasonic wave generating part (f) [Equation 1]

Node position of standing wave (cm)=Integer (n) of 1 to 10×Wavelength of ultrasonic wave (λ)/2 [Equation 2]

The wavelength (λ) of the ultrasonic wave can be calculated using Equation 1, and then the node position (cm) of the standing wave can be calculated using Equation 2. By vertically moving in the z-axis direction (vertical direction to the bottom surface of the accommodating part) within the depth where the standing wave is possible, the interface between the substrate and the LED element can be matched to the node position of the standing wave. Here, the standing wave represents a form in which a wave is trapped in a limited space and vibrates in place, and is a wave in which the position of the node is fixed.

The matching of the interface to the node position of the standing wave can be performed by vertically moving the substrate to which the holder is attached from the surface of the organic solvent.

Therefore, when a vertical movement distance of the substrate to which the holder is attached from the surface of the organic solvent is D, and a height of the organic solvent is L,

D=L−Node position of standing wave (cm) may be satisfied. [Equation 3]

For example, an accommodating part under which an ultrasonic wave generating part is disposed is provided, and an organic solvent is introduced into the accommodating part. Then, a holder is attached to the opposite surface of the substrate on which a plurality of LED elements are formed, and then the holder is moved vertically to introduce the substrate into the accommodating part.

Subsequently, the surface of the substrate and the surface of the organic solvent are matched.

Using [Equation 1] Wavelength of ultrasonic wave (2)=Speed of ultrasonic wave in organic solvent (v)/Vibration frequency of ultrasonic wave generating part (f), when the vibration frequency (f) of the ultrasonic wave generating part is 132 kHz and the ultrasonic wave velocity in the organic solvent is 1125 m/s, the wavelength (λ) of ultrasonic waves is (1.13×10³ m/s)/(1.32×10⁵/s)=0.86 cm.

In [Equation 2] Node position of standing wave (cm)=Integer (n) of 1 to 10×Wavelength of ultrasonic wave (λ)/2, when n is set to 3, the node position of standing wave (cm) is 3 22=1.29 cm.

In other words, when the height of the organic solvent L=5 λ=4.3 cm, if applied to [Equation 3] Vertical movement distance D of the substrate to which the holder is attached from the surface of the organic solvent=height L of the organic solvent-node position (cm) of the standing wave, D is 4.3 cm−1.29 cm=3.01 cm.

In order to maximize the effect of bubble generation by high frequency and wave energy (shock wave), the substrate to which the holder is attached is moved downward (z-axis direction) by 3.01 cm from the surface of the organic solvent, so that the interface between the substrate and the LED element can be matched to the position of 1.29 cm, which is the node position of the standing wave.

Thereafter, ultrasonic waves are applied to the substrate to generate bubbles in the organic solvent, and the generated bubbles penetrate between a plurality of LED elements, so that the plurality of LED elements can be separated from the substrate.

When pressure is generated in the organic solvent by high-frequency ultrasonic waves, microbubbles are generated, and the size of the bubbles may be smaller than a gap between one LED element and another LED element formed on the substrate. Since the size of the bubbles is the same as described above in the second embodiment, the details thereof will be omitted.

In addition, the vibration frequency of the ultrasonic wave generating part is preferably 120 to 200 kHz, and in this range, there is an effect of maximizing the separation efficiency of the LED element together with the wave energy.

Since the details about the vibration frequency are the same as described above in the second embodiment, the details thereof will be omitted.

As described above, the LED element separation method according to the third embodiment of the present invention uses high-frequency ultrasonic waves and wave energy in a state where the direction of the LED element formed on the substrate faces downward, thereby having the effect of further improving the separation yield by physical impact force.

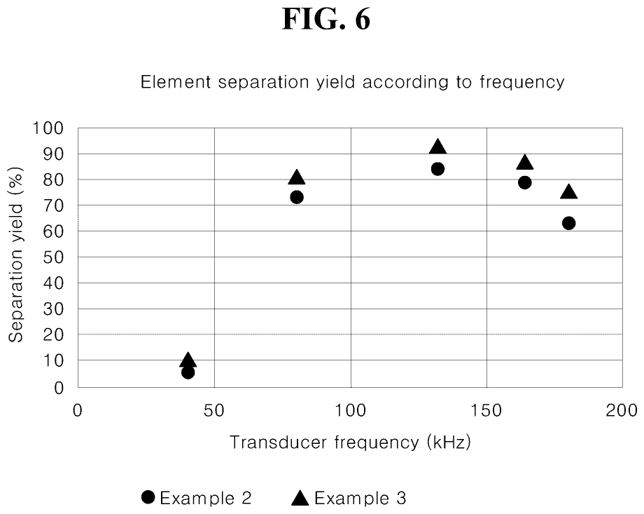

FIG. 6 is a graph showing the separation yield of LED elements according to frequency in the second and third embodiments of the present invention.

In the process of testing the separation yield of LED elements according to frequency in the second embodiment (Example 2) and the third embodiment (Example 3), it was confirmed that the size of the microbubbles generated by the ultrasonic waves decreased in inverse proportion to the frequency. When the ultrasonic frequency was 40 kHz or more and less than 80 kHz, the size of the microbubbles was more than 10 μm and 50 μm or less, and when it was 120 to 200 kHz, the size of the microbubbles was 1 to 10 μm.

Referring to the graphs of Examples 2 and 3 in FIG. 6, the reason why the separation efficiency is as low as 20% or less when the ultrasonic frequency is around 40 kHz is that the size of the microbubbles is large and thus they cannot penetrate between the LED elements. It is considered that the separation efficiency is not high because the energy transferred to the interface between the LED elements is small.

It seems that when the ultrasonic frequency is 80 kHz or more and 170 kHz or less, the size of the microbubbles is similar to the gap between the LED elements, so the energy is efficiently transferred. Accordingly, the separation efficiency was 70% or higher.

When the ultrasonic frequency exceeds 170 kHz, the size of the microbubbles decreases, so the penetration ability between the LED elements is good. However, since the size of the microbubbles is too small and the energy generated is small, there is a disadvantage in that it is difficult to efficiently separate the LED elements.

In particular, looking at the graph of Example 3 using the microbubbles and the node positions of the standing wave, it can be seen that the energy is well transferred to the interface between the substrate and the LED elements, so that the separation yield of the LED elements is further improved. This shows that it is possible to improve the separation yield by using physical impact force.

Therefore, it can be confirmed that the separation efficiency of the LED elements is excellent when the ultrasonic frequency of the present invention is 80 to 180 kHz, and the separation efficiency of the LED elements is even better when it is 120 to 170 kHz.

Although the present invention has been described with reference to the exemplified drawings above, the present invention is not limited to the embodiments and drawings disclosed in this specification, and it is obvious that various modifications can be made by those skilled in the art within the scope of the technical idea of the present invention. In addition, even if the operations and effects according to the configuration of the present invention were not explicitly described while describing the embodiments of the present invention, it is natural that the effects predictable by the corresponding configuration should also be acknowledged.

1. A system for separating an LED element using a hydrophobically modified LED element, the system comprising:
a first accommodating part for accommodating a substrate on which a plurality of LED elements are formed and an organic solvent;
a second accommodating part disposed outside the first accommodating part and accommodating the first accommodating part and a fluid;
a plurality of ultrasonic wave generating parts disposed under the second accommodating part and applying ultrasonic waves to the substrate; and
a passage part which is connected to the second accommodating part and through which the fluid circulates,
wherein the plurality of LED elements include a modifying compound on the surface thereof,
wherein the modifying compound includes a hydrophilic functional group located on the surface of the LED element and a hydrophobic functional group located on the opposite side of the hydrophilic functional group.

2. The system for separating an LED element according to claim 1, wherein the modifying compound has a weight average molecular weight of 500 g/mol or less.

3. The system for separating an LED element according to claim 1, wherein the hydrophilic functional group of the modifying compound includes phosphonic acid, and the hydrophobic functional group includes a C1 to C18 alkyl group.

4. The system for separating an LED element according to claim 1, wherein the organic solvent accommodated in the first accommodating part is maintained at a temperature of 20 to 30° C.

5. The system for separating an LED element according to claim 1, wherein the plurality of ultrasonic wave generating parts apply ultrasonic waves to one surface of the substrate in a direction perpendicular thereto and are driven simultaneously.

6. The system for separating an LED element according to claim 1, wherein the system further comprises a cooling part located in the passage part.

7-14. (canceled)
